(19) United States
(12) Patent Application Publication
(10) Pub. No.: US 2018/0374737 A1
(43) Pub. Date: Dec. 27, 2018

(54) HIGH TEMPERATURE HEAT PLATE PEDESTAL

(71) Applicant: Watlow Electric Manufacturing Company, St. Louis, MO (US)

(72) Inventor: Patrick Margavio, Columbia, MO (US)

(73) Assignee: Watlow Electric Manufacturing Company, St. Louis, MO (US)

(21) Appl. No.: 16/017,312

(22) Filed: Jun. 25, 2018

Related U.S. Application Data
(60) Provisional application No. 62/658,770, filed on Apr. 17, 2018.
(60) Provisional application No. 62/523,976, filed on Jun. 23, 2017.

(51) Int. Cl. H01L 21/683; H01L 21/67; F28D 15/04; F28F 21/04

(52) U.S. Cl. CPC H01L 21/6833; F28F 21/04; F28D 15/046; H01L 21/67103

(57) ABSTRACT

An assembly, which in one form is a pedestal, includes an upper member, a lower member bonded to the upper member, and a thermal phase diffuser disposed between the upper member and the lower member within a hermetically sealed volume. The thermal phase diffuser diffuses heat by way of a phase change of a working fluid within the hermetically sealed volume. The assembly/pedestal is capable of operating at high temperatures, in excess of 1000° C., with a high degree of temperature uniformity, and in one form is an aluminum nitride (AlN) material.

### CROSS-REFERENCE TO RELATED APPLICATIONS

The present application claims the benefit of U.S. Provisional Application No. 62/523,976, titled “High Temperature Heat Plate Pedestal” and filed Jun. 23, 2017, and U.S. Provisional Application No. 62/658,770, titled “High Temperature Oscillating Heat Pipe Pedestal” and filed Apr. 17, 2018, the contents of which are incorporated herein by reference in their entirety.

### FIELD

The present disclosure relates generally to semiconductor processing equipment, and more particularly to pedestals and/or electrostatic chucks for supporting, heating, or cooling a wafer thereon during various semiconductor processing steps.

### BACKGROUND

The statements in this section merely provide background information related to the present disclosure and may not constitute prior art.

Pedestals are known in semiconductor processing to support and heat a wafer disposed thereon. A pedestal generally includes a plate member for supporting a wafer and a shaft member attached to a bottom side of the plate member. A heater may be embedded in the plate member to provide the required heating to the wafer. Additionally, an electrostatic chuck or a cooling device may be bonded to or embedded within the plate member of the pedestal to provide electrostatic chucking force or cooling to the wafer.

During various wafer processing steps, such as plasma enhanced film deposition, or etching, a wafer support surface of the plate member needs to be uniformly heated or cooled to reduce processing variations within the wafer. Therefore, the heater or the cooling device needs to be specially configured to provide uniform heating/cooling to the wafer, resulting in a complex design of the heating/cooling circuit.

Moreover, the wafer support surface needs to be rapidly heated or cooled to reduce total processing time. A typical heater for the pedestal may have a multi-layered structure, including, for example, a resistive heating layer, a routing layer, dielectric layers and protective layers. The multi-layered structure of the heater and the laminate of the electrostatic chuck, the heater, and the cooling device undesirably limits the heating/cooling rate of the wafer by adding thermal barriers in the z-axis through the pedestal.

Further, the materials for forming the various layers of the assembly are limited due to coefficients of thermal expansion (CTE) compatibility among these materials. When materials having incompatible CTE, cracking or delamination may occur, particularly at an elevated temperature. The operating temperature of the pedestal may also be limited by the material of the resistive heating layer or due to the incompatibility of the CTE among some of the material layers. Typically, a pedestal can be operated at an operating temperature below 700° C.

### SUMMARY

In one form, an assembly is provided, (which in one form is a pedestal for semiconductor processing applications) that includes an upper member, a lower member, and a thermal phase diffuser disposed between the upper member and the lower member within a hermetically sealed volume. The thermal phase diffuser diffuses heat by way of a phase change of a working fluid within the hermetically sealed volume.

In one variation, a filling material is disposed within a gap between the thermal phase diffuser and the lower member. The filling material may be a high temperature compressible material such as, by way of example, Grafoil, aluminum nitride (AlN) powder, ceramic paste, and flexible graphite/graphene.

In other variations, a bonding layer is disposed between the upper member and the thermal phase diffuser, which in one form is a titanium-nickel braze alloy.

The upper member may include an upper wall and a peripheral wall extending downwardly from the upper wall, the thermal phase diffuser being surrounded by the peripheral wall of the upper member. In one variation of this form, the lower member is bonded to the peripheral wall of the upper member. The upper member and the lower member may be made of different materials, or of the same materials.

In one form, the thermal phase diffuser includes a tubular shell having a T-shape cross section. In another form, the thermal phase diffuser further includes a wick structure, the wick structure defining a vapor guiding channel. Vapor of the working fluid flows in the vapor guiding channel and liquid of the working fluid flows along the wick structure and outside the vapor guiding channel. In one variation, the vapor of the working fluid flows in a direction perpendicular to the upper member.

In another form, the thermal phase diffuser includes a plate portion and a shaft portion extending from a lower surface of the plate portion and being perpendicular to the plate portion. A shaft member may be disposed under the lower member, and the filling material may also be disposed between the shaft member and the shaft portion of the thermal phase diffuser.

The working fluid may be selected from a group consisting of liquid helium, mercury, sodium, sulphur, halides, indium, Cesium, NaK, potassium, lithium, sliver, ammonia, alcohol, methanol, ethanol, acetone, methyl alcohol, water, Naphthalene, or other molten materials.

In yet another form, a resistive heater surrounds a portion of the thermal phase diffuser. In another form, the upper member is bonded to the lower member, while in another form, the upper member and the lower member are a single unitized part.

In another form of the present disclosure, an assembly is provided that comprises a ceramic substrate defining a hermetically sealed fluid channel containing a working fluid and a thermal phase diffuser disposed within the hermetically sealed fluid channel. The working fluid flows in the hermetically sealed fluid channel and includes a plurality of discrete liquid slugs and vapor bubbles. In one variation of this form, the vapor bubbles release heat and condense proximate one of a center and a peripheral portion of the substrate and the liquid slugs absorb heat and evaporate proximate the other one of the center and the peripheral portion of the substrate. The ceramic substrate has a high thermal conductivity in one form and is made of an Aluminum Nitride (AlN) material.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The present disclosure will become more fully understood from the detailed description and the accompanying drawings, wherein:

FIG. 1 is a cross-sectional view of a pedestal constructed in accordance with a first form of the present disclosure;

FIG. 2 is a cross-sectional view of a variant of the pedestal of FIG. 1;

FIG. 3 is a top view of a thermal phase diffuser of the pedestal of FIG. 1;

FIG. 4 is a side view of the thermal phase diffuser of FIG. 3;

FIG. 5 is a cross-sectional view of a pedestal constructed in accordance with another form of the present disclosure;

FIG. 6 is a schematic view of the thermal phase diffuser as shown in FIGS. 1 to 5, wherein the thermal phase diffuser includes a vapor-chamber-type heat pipe;

FIG. 7 is a cross-sectional view of a pedestal constructed in accordance with another form of the present disclosure, wherein the pedestal includes a vapor-chamber-type heat pipe;

FIG. 8 is a cross-sectional view of a pedestal constructed in accordance with another form of the present disclosure, wherein the pedestal includes a vapor-chamber-type heat pipe;

FIG. 9 is a cross-sectional view of a pedestal constructed in accordance with another form of the present disclosure, wherein the pedestal includes a vapor-chamber-type heat pipe;

FIG. 10 is a top view of a diffuser integrated in the pedestal of FIG. 9;

FIG. 11 is a top cross-sectional view of a variant of a thermal phase diffuser of the pedestal as shown in FIGS. 1 to 5, wherein the thermal phase diffuser includes an oscillating heat pipe (OHP);

FIG. 12 is a cross-sectional view of a plate portion of the thermal phase diffuser of FIG. 11;

FIG. 13 is a cross-sectional view of a plate portion of a thermal phase diffuser and a fill tube that allows a working fluid to fill in a fluid channel of the plate portion according to the teachings of the present disclosure;

FIG. 14 is a cross-sectional view of a plate portion of a thermal phase diffuser and a crimped fill tube after the working fluid fills in the fluid channel according to the teachings of the present disclosure;

FIG. 15 is a cross-sectional view of a pedestal constructed in accordance with another form of the present disclosure, wherein the pedestal includes an oscillating heat pipe (OHP);

FIG. 16 is a cross-sectional view of a pedestal constructed in accordance with another form of the present disclosure, wherein the pedestal includes an oscillating heat pipe (OHP);

FIG. 17 is a cross-sectional view of a pedestal constructed in accordance with another form of the present disclosure, wherein the pedestal includes an oscillating heat pipe (OHP);

FIG. 18 is a top view of a diffuser integrated in the pedestal of FIG. 17;

FIG. 19 is cross-sectional view of a thermal system in the form of a gas line heating assembly constructed in accordance with the teachings of the present disclosure;

FIG. 20 is cross-sectional view of a variant of a thermal system in the form of a gas line heating assembly constructed in accordance with the teachings of the present disclosure;

FIG. 21 is a schematic view of a thermal system for providing radiative heat to a wafer in a semiconductor processing chamber constructed in accordance with the teachings of the present disclosure;

FIG. 22 is a schematic view of a variant of a thermal system constructed in accordance with the teachings of the present disclosure; and

FIG. 23 is a schematic view of a thermal system used as a temperature sensor constructed in accordance with the teachings of the present disclosure.

Corresponding reference numerals indicate corresponding parts throughout the several views of the drawings.

### DETAILED DESCRIPTION

The following description is merely exemplary in nature and is not intended to limit the present disclosure, application, or uses.

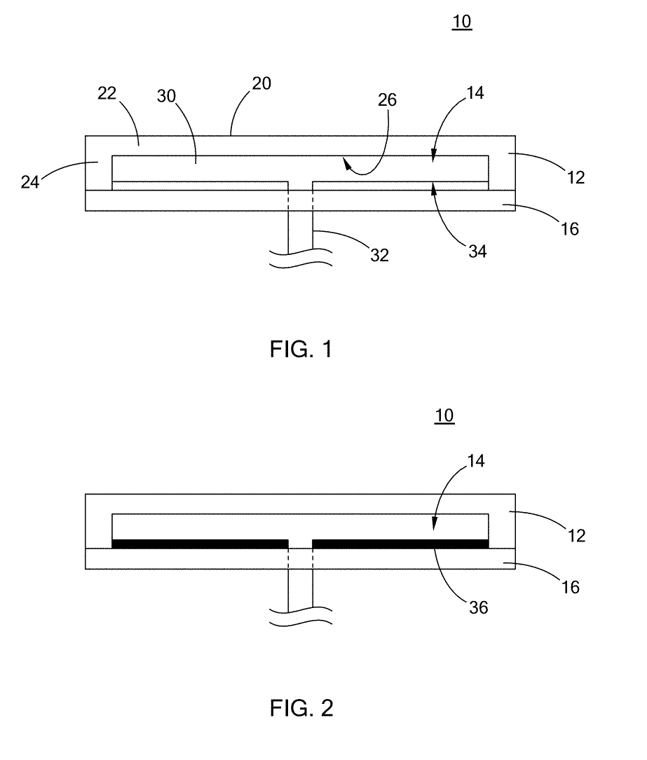

Referring to FIG. 1, an assembly, which in this illustrative form is a pedestal 10, is shown constructed in accordance with one form of the present disclosure. The pedestal 10 includes an upper member 12, a thermal phase diffuser 14, and a lower member 16. The upper member 12 defines an upper surface 20, which may be a wafer support surface, or an interface surface to which another device, such as an electrostatic chuck, or an RF member, is bonded. Alternatively, electrode(s) of an electrostatic chuck or the RF member may be embedded in the upper member 12. The upper surface 20 of the upper member 12 can also be bonded to a wafer support portion of a typical pedestal made of aluminum nitride (AlN).

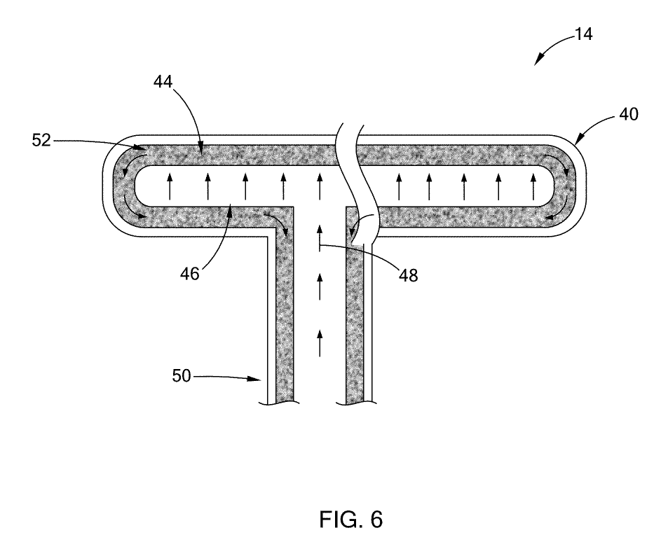

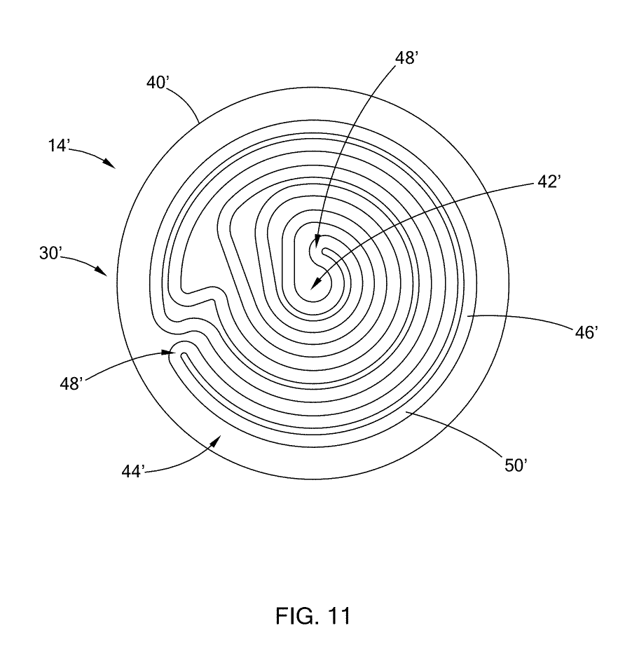

Certain features of the thermal phase diffuser 14 are provided such that the thermal phase diffuser 14 can function as a heater, a cooling device, or a high heat capacity diffuser. These features can generally be referred to as a “heat pipe” and are described in greater detail below. Therefore, the function of heating provided by the thermal phase diffuser 14 in one form of the present disclosure should not be construed as limiting the scope of the present disclosure. The thermal phase diffuser 14 in one form (as shown in FIG. 6) may include a vapor-chamber-type heat pipe and in another form (as shown in FIG. 11) may include an oscillating heat pipe (OHP), which will be described in more detail below. Accordingly, as used herein, the term “thermal phase diffuser” should be construed to mean a thermal diffuser that diffuses heat by way of a phase change of a working fluid that moves within a hermetically sealed/constrained volume.

The upper member 12 defines an inverted U shape and has an upper wall 22 and a peripheral wall 24 extending downwardly from the upper wall 22. A cavity 26 is defined between the upper wall 22 and the peripheral wall 24 of the upper member 12. In one form, the thermal phase diffuser 14 has a T-shape cross-section and includes a plate portion 30 disposed in the cavity 26 and a shaft portion 32 extending downwardly from the plate portion 30. A gap 34 is defined between the plate portion 30 of the thermal phase diffuser 14 and an upper surface of the lower member 16.

In one form, the gap 34 may be left empty to accommodate thermal expansion between the thermal phase diffuser 14 and the lower member 16. In another form, the gap 34 may be filled with a filling material 36, such as a high temperature compressible material, including but not limited to Grafoil, aluminum nitride (AlN) powder, ceramic paste, and flexible graphite/graphene, as shown in FIG. 2. The filling material 36 functions both mechanically and thermally. More specifically, the filling material 36 functions mechanically to absorb and transfer mechanical loads between the lower member 16 and the thermal phase diffuser 14. The filling material 36 also functions to transfer heat between the lower member 16 and the thermal phase diffuser 14. Further, the filling material 36 may fill the gap 34 completely or at predetermined locations/intervals. Being a high temperature compressible material, the filling material 36 can ensure proper bonding between the lower member 16 and the thermal phase diffuser 14 even if the plate portion 30 of the thermal phase diffuser 14 has a Coefficient of Thermal Expansion (CTE) incompatible with the CTE of the lower member 16.

The upper member 12 may include a ceramic material, such as aluminum nitride (AlN). The lower member 16 may include a material that is the same as or different from the material of the upper member 12. The upper member 12 and the lower member 16 are separately formed and bonded along the peripheral wall 24 of the upper member 12. The lower member 16 may be formed of a material having a much lower thermal conductivity (such as zirconia) than the material of the upper member 12 so that heat generated by the thermal phase diffuser 14 is primarily directed toward the upper member 12 with less heat being directed to the lower member 16 to avoid heat loss. Because the upper member 12 is bonded to the lower member 16 only along the peripheral wall 24, the incompatibility of the CTEs between the upper member 12 and the lower member 16 is less of concern when the lower member 12 is also bonded to the thermal phase diffuser 14 by the filling material 36. As such, a wider selection of materials can be used for the lower member 12.

The thermal phase diffuser 14 and the upper member 12 may be bonded by titanium-nickel braze alloys. The upper member 12 may be a metalized ceramic or a non-metallized ceramic depending on the braze alloy that bonds the upper member 12 to the thermal phase diffuser 14. In either case, the titanium-nickel braze alloys allow for better thermal contact between the thermal member 14 and the upper member 12 than compressible material or mechanical interface.

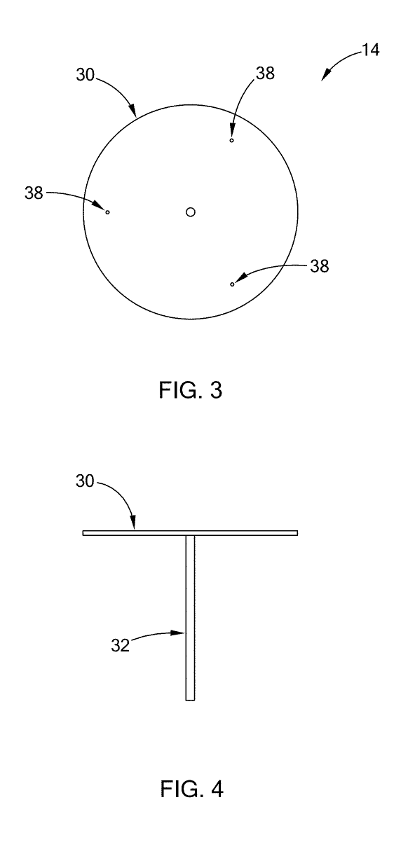

Referring to FIGS. 3 and 4, the thermal phase diffuser 14 has a heat pipe configuration and, in one form, has a T-shape cross section. The thermal phase diffuser 14 includes a plate portion 30 and a shaft portion 32. Three through holes 38 are formed in the plate portion 30, which can provide a variety of functions, but are used here as lift pin holes in this form of the present disclosure.

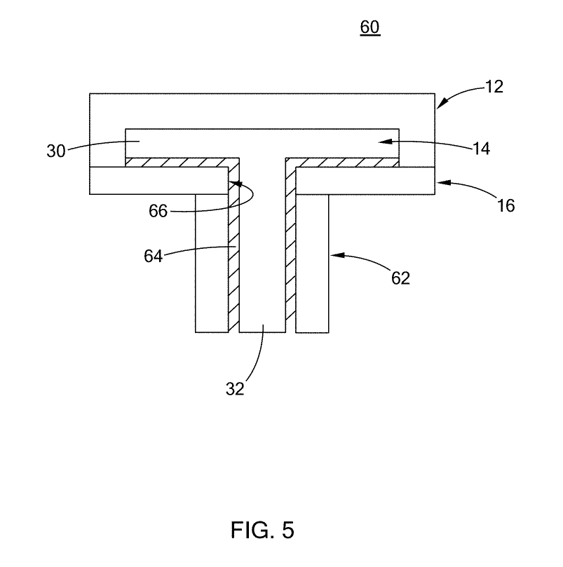

Referring to FIG. 5, a pedestal 60 constructed in accordance with a second form of the present disclosure is similar to the pedestal 10 of the first form except that the pedestal 60 includes a tubular shaft member 62 and a filling material 64 between the tubular shaft member 62 and the thermal phase diffuser 14. Like elements will be indicated by like reference numerals and the detailed description will be omitted herein for clarity.

More specifically, the pedestal 60 includes an upper member 12, a thermal phase diffuser 14, a lower member 16, and a shaft member 62 disposed under the lower member 16. The thermal phase diffuser 14 in one form (as shown in FIG. 6) may include a vapor-chamber-type heat pipe and in another form (as shown in FIG. 11) may include an oscillating heat pipe (OHP). A gap 66 is defined between the plate portion 30 of the thermal phase diffuser 14 and an upper surface of the lower member 16 and between the tubular shaft portion 32 of the thermal phase diffuser 14 and the shaft member 62. The filling material 64 is filled in the gap 66, either completely or at predetermined locations/spacing. The filling material 66 may be selected from the group consisting of Grafoil, aluminum nitride (AlN) powder, ceramic paste, and flexible graphite/graphene. The filling material 66 may be selected to have a coefficient of thermal expansion (CTE) between the CTE of the outer shell 32 of the thermal phase diffuser 14 and the CTE of the lower member 16 to reduce the thermal stress caused by the CTE differences between the plate portion 30 of the thermal phase diffuser 14 and the lower member 16. The filling material 66 also thermally and dielectrically insulates the thermal phase diffuser 14 within the tubular shaft member 62.

The pedestal 60 may be used in an AlN pedestal, or in an Aluminum pedestal/wafer heating plate. While the pedestal 60 is mainly described to be used for semiconductor processing, such as deposition or etching, the pedestal 60 can also be used as a general heating plate for heating a target. The pedestal 60 may be used at relatively lower temperature, such as 30° C. within a lithography system, as a diffuser plate and/or to provide heating and cooling. The suitable working fluid for the heat pipe of the thermal phase diffuser 14 for this operating temperature includes, but is not limited to, ammonia, methanol, and water.

Thermal Phase Diffuser Including Vapor-Chamber-Type Heat Pipe

Referring to FIG. 6, the thermal phase diffuser 14, in one form, may have a vapor-chamber-type heat pipe configuration and include a tubular shell 40 and a wick structure 44 disposed inside the tubular shell 40. The wick structure 44 defines a vapor guiding channel 46 or a vapor guiding chamber. The tubular shell 40 is sealed and partially filled with a working fluid 48.

The working fluid 48 flows inside the tubular shell 40 in both its vapor and liquid form over a desired operating temperature range. The working fluid 48 may be liquid helium, mercury, sodium (500 to 1450 C), indium, Cesium, NaK, potassium (400 to 1000° C.), lithium (900 to 1700 C), sliver, ammonia, alcohol, methanol, ethanol, acetone, methyl alcohol, water (25 to 327 C), naphthalene (330 to 450 C), or other molten materials, depending on a desired operating temperature. For room temperature applications, water may be used as the working fluid. For higher temperature applications, mercury (523-923K), sodium (873-1473K) or indium (2000-3000K) may be used as the working fluid.

The material of the tubular shell 40 is chosen to be compatible with the working fluid 48. A wide selection of materials may be used to form the tubular shell 40 for elevated temperature applications, including but not limited to, Stainless Steel, Incoloy, Titanium, Inconel, Tungsten, Niobium, and Molybdenum. When water is used as the working fluid 48, the tubular shell 40 may be made of copper. When ammonia is used as the working fluid 48, the tubular shell 40 may be made of aluminum.

The tubular shell 40 includes a higher temperature end 50 adjacent to the shaft portion 32 and a lower temperature end 52 adjacent to a top surface of the plate portion 30 of the tubular shell 40.

In another form, the thermal phase diffuser 14 may have only the plate portion 30 without the shaft portion 32. A separate shaft member may be used to be attached to the lower member 16 of the pedestal 10. In this case, the higher temperature end 50 is adjacent to the lower member 16 and the lower temperature end 52 is adjacent to the upper member 12.

For the thermal phase diffuser 14 to transfer heat, the working fluid 48 including both saturated liquid and its vapor (gas phase) is contained in the tubular shell 40. The saturated liquid vaporizes to vapor at the higher temperature end 50, absorbing thermal energy at the higher temperature end 50 of wick structure 44.

The vapor travels to the lower temperature end 52 along the vapor guiding channel 46, where the vapor condenses into liquid, releasing latent heat at the lower temperature end 52 of the wick structure 44. The condensed liquid is absorbed by the wick structure 44 and is returned back to a saturated liquid. The condensed liquid is returned back to the higher temperature end 52 using the wick structure 44 outside the vapor guiding channel 46 through a capillary action on the liquid phase of the working fluid 48, thereby completing a thermal cycle.

The wick structure 44 may include sintered porous metal powder, meshed screen, fiberglass and/or narrow grooves to guide the condensed liquid back to the higher temperature end 52. Generally, an effective wick structure 44 requires small surface pores for large capillary pressure, large internal pores for minimal liquid-flow resistance, and an uninterrupted highly conductive heat-flow path across the wick thickness for a small temperature drop. The thermal conductivity of the heat pipe can exceed 5000 W/mK.

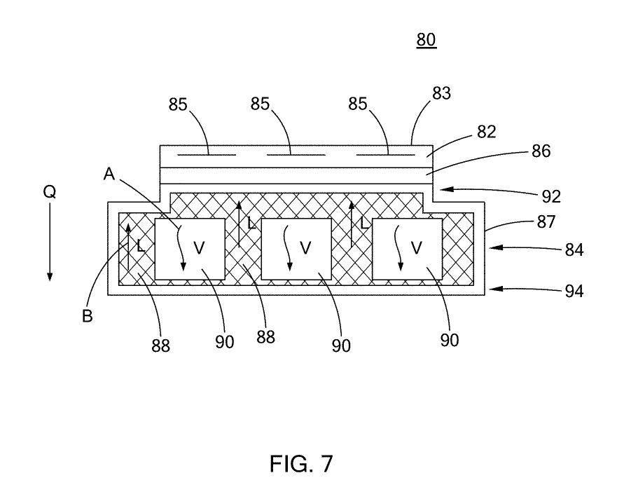

Referring to FIG. 7, a pedestal 80 constructed in accordance with another form of the present disclosure includes an integrated electrostatic chuck (ESC) and an integrated cooling device. The shaft member of the pedestal 80 is not shown in FIG. 7 and the description thereof is omitted herein for clarity. The pedestal 80 of the present form may be operated at an operating temperature in the range of 150° C. to 300° C., which is significantly lower than the operating temperature of the pedestals 10, 60 of the previously illustrated forms.

More specifically, the pedestal 80 includes an upper member in the form of an ESC 82, a thermal phase diffuser in the form of a cooling device 84, and a bonding layer 86 for bonding the ESC 82 to the cooling device 84, and optionally a shaft member (not shown in FIG. 7) disposed under the cooling device 84. The ESC 82 includes a chuck body 83 made of a ceramic material and electrodes 85 embedded therein to providing the electrostatic chucking force to the wafer (not shown) disposed thereon. The cooling device 84, in one form, may be a heat pipe and may have a plate configuration. The cooling device 84 includes a tubular shell 87, a wick structure 88, a plurality of vapor guiding channels 90 defined in the wick structure 88, and a working fluid 90 in both vapor and liquid forms. The vapor guiding channels 90 each has a higher temperature end 92 adjacent to an upper surface of the tubular shell 86 and a lower temperature end 94 adjacent to a lower surface of the tubular shell 87.

The vapor V of the working fluid 90 flows in the vapor guiding channels 90 and away from the chuck body 82, i.e., from the higher temperature end 92 toward the lower temperature end 94, as indicated by arrow A. The liquid of the working fluid 90 absorbs heat from the ESC 82 and evaporates at the higher temperature end 92, thereby cooling the ESC 82. The vapor of the working fluid 90 travels down to the lower temperature end 92 and condenses into liquid at the lower temperature end 94, releasing latent heat. The condensed liquid L is absorbed by the wick structure 88 and then flows up along the wick structure 88 outside the vapor guiding channels 90 toward the higher temperature end 92, as indicated by arrow B, and evaporates again at the higher temperature end 92 to start another thermal cycle. Therefore, the thermal power Q flows from the ESC 82 towards a bottom surface of the cooling device 84. The tubular shell 86 of the cooling device 84 may be made of copper and the working fluid 90 may be water.

In this form, the cooling device 84 is shown to be applied to a bottom surface of the ESC 82. Alternatively, the cooling device 84 may be embedded within the chuck body 83 of the ESC 82.

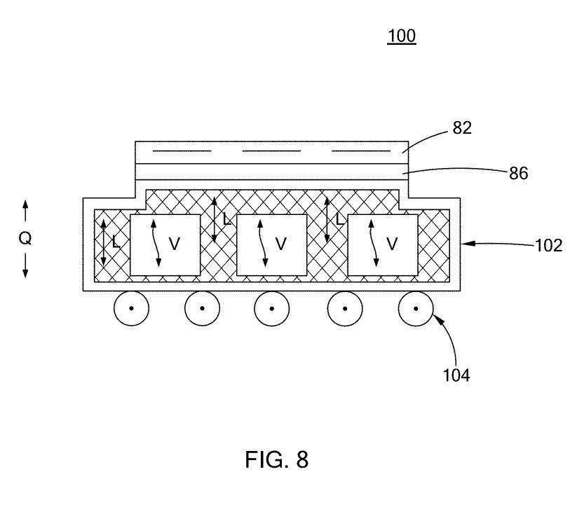

Referring to FIG. 8, a pedestal 100 constructed in accordance with the teachings of another form includes an upper member in the form of an integrated ESC and a thermal phase diffuser in the form of a heating/cooling device. The shaft member of the pedestal 100 is optional and is not shown in FIG. 8 and thus the description thereof is omitted herein for clarity.

More specifically, the pedestal 100 includes an ESC 82 similar to that of FIG. 7, a heating/cooling device 102, and a supplemental heater 104 disposed at a bottom surface of the heating/cooling device 102, which may be a resistive heater in one form of the present disclosure. The supplemental heater 104 is disposed outside the ceramic stack to minimize thickness and thermal resistance. The heating/cooling device 102 has a structure similar to that of the cooling device 84 of FIG. 7 except that the vapor can be controlled to move up toward the ESC 82 or down away from the ESC 82. When the vapor moves up toward the ESC 82, the heating/cooling device 102 functions as a heating device. When the vapor moves down away from the ESC 82, the heating/cooling device 102 functions as a cooling device. Therefore, the thermal power Q may flow in either direction.

The supplemental heater 104 may be a less expensive and lower precision heater attached to the bottom surface of the heating/cooling device 102. In the present form, the tubular shell of the heating/cooling device 102 may be made of copper and the working fluid may be water.

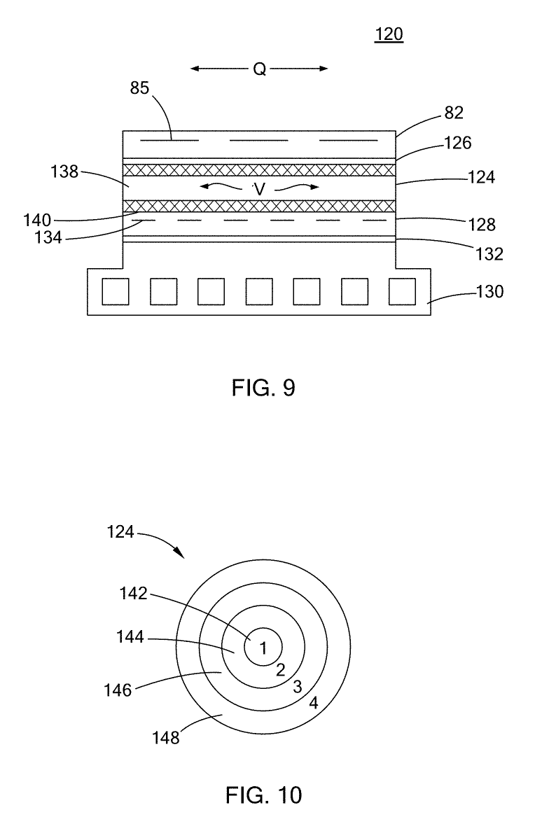

Referring to FIG. 9, the pedestal 120 constructed in accordance with another form of the present disclosure includes an integrated diffuser. The tubular shaft member is optional and is not shown in FIG. 9.

More specifically, the pedestal 120 includes an upper member in the form of an ESC 82, a thermal phase diffuser in the form of a diffuser 124, a first bonding layer 126 between the ESC 82 and the diffuser 124, a heater 128, a base plate 130, and a second bonding layer 132 disposed between the heater 128 and base plate 130. The base plate 130 is used for cooling and also for dimensional alignment and thermal mass during processing. The ESC 82 is similar to the ones of FIGS. 7 and 8. The heater 128 may be a conventional heater including a plurality of resistive heating elements 134. The diffuser 124 is a heat pipe and has a structure similar to that of FIGS. 7 and 8 except for the orientation of the vapor guiding channel 138. In the present form, the vapor guiding channel 138 has a higher temperature end and a lower temperature end along the radial direction of the diffuser 124. The vapor guiding channel 138 guides the vapor to flow in the radial direction. The thermal power Q moves in a radial direction, either inwardly or outwardly.

Referring to FIG. 10, the diffuser 124 has a plate configuration and defines a plurality of annular regions, for example, region 1, region 2, region 3, region 4. The annular regions are in different radial positions relative to the center of the diffuser 124. The diffuser 124 allows for radial tuning. A heating surface may not provide uniform heating along the radial direction of the heating surface due to the presence of heat sinks along the peripheral portion of the diffuser 124. The diffuser 124 allows for heat transfer along a radial direction, either from a center toward a peripheral end, or from a peripheral end toward the center. The center of the diffuser 124 may have a temperature higher or lower than the temperature of the peripheral end of the diffuser 124, thereby fine-tuning the temperature of the heating surface along the radial direction to achieve a more uniform heating surface.

Alternatively, the diffuser 124 may include a plurality of concentric ring plates 142, 144, 146, 148, each ring plate including a heat pipe structure to conduct heat transfer within each ring plate and in the radial direction. Therefore, one radial end of the ring plate has a temperature higher than the other radial end of the ring plate.

Thermal Phase Diffuser Including Oscillating Heat Pipe

Referring to FIG. 11, the thermal phase diffuser 14 as shown in FIGS. 1 to 5 may alternatively be configured to be a thermal phase diffuser 14′ having an oscillating heat pipe (OHP) configuration. Like the thermal phase diffuser 14, the thermal phase diffuser 14′ includes a thermal plate portion 30′ and optionally a shaft portion.

More specifically, the thermal plate portion 30′ of the thermal phase diffuser 14′ includes a substrate 40′ and at least one channel 46′ defined in the substrate 40′. The channel 46′ has a serpentine shape with the bend portions 48′ disposed adjacent to a center 42′ and a peripheral portion 44′ of the thermal plate portion 30′ as shown, thereby forming the continuous channel 46′. A working fluid 50′ flows inside the channel 46′ in both a vapor phase and a liquid phase over a desired operating temperature range. The working fluid 50′ disperses into a chain of discrete liquid phase (called “liquid slugs”) and vapor phase (called “vapor bubbles”).

A heat source (not shown) may be disposed proximate the center 42′ of the thermal plate portion 30′ so that the center 42′ of the thermal plate portion 30′ constitutes an evaporator side. The peripheral portion 44′ of the thermal plate portion 30′ is cooler than the center 42′ of the thermal plate portion 30′ and thus constitutes a condenser side. As the liquid slugs move towards the center 42′ of the thermal plate portion 30′ (i.e., the evaporator side), the liquid slugs are partially evaporated so that the vapor bubbles absorb the fluid's latent heat and expands. As the vapor bubbles move from the center 51′ towards the peripheral portion 44′ (i.e., the condenser side) of the thermal plate portion 30′, heat is removed by the heat sinks adjacent to the peripheral portion 44′ of the thermal plate portion 30′, causing the vapor bubbles to release the vapor's latent heat, partially condense and contract. Therefore, the peripheral portion 44′ of the thermal plate portion 30′ is heated due to release of vapor bubbles' latent heat. Heat from the center 42′ of the thermal plate portion 30′ can be quickly spread to the peripheral portion 44′ of the thermal plate portion 30′.

Alternatively, a heat source may be disposed proximate the peripheral portion 44′ of the thermal plate portion 30′ so that the peripheral portion 44′ constitutes an evaporator side and the center 42′ of the thermal plate portion 30′ constitutes a condenser side. As the working fluid 50′ moves from the center 42′ towards the peripheral portion 44′, the liquid slugs are partially evaporated so that the vapor bubbles absorb the fluid's latent heat and expands. As the vapor bubbles move from the peripheral portion 44′ towards the center 42′, heat is removed by the heat sinks adjacent to the center 42′, causing the vapor bubbles to release the vapor's latent heat, partially condense and contract. Therefore, the center 42′ of the thermal plate portion 30′ is heated due to release of vapor bubbles' latent heat. Heat from the peripheral portion 44′ of the thermal plate portion 30′ can be quickly spread to the center 42′ of the thermal plate portion 30′.

By repeatedly moving the working fluid 50′ between the cold condenser side and the hot evaporator side, the working fluid 50′ oscillates in the plane of the thermal plate portion 30′ and repeatedly absorbs heat proximate the center 42′ (or the peripheral portion 44′) and releases heat proximate the peripheral portion 44′ (or the center 42′). In one form, the channel 46′ may have a small diameter and be a microchannel, such that the working fluid 50′ can flow in the channel 46′ through capillary action without the assistance of any external force. The microchannel may include any of a variety of cross-sectional geometries such as, by way of example, circular, u-shaped, or other polygonal shapes depending on a desired pressure distribution within the microchannel(s) 46′.

A wick structure, which is required in a vapor-chamber-type heat pipe, is not required in the OHP configuration. Therefore, the thermal plate portion 30′ using an OHP configuration has a more simplified structure and can be made thinner, thereby reducing the manufacturing costs.

The working fluid 50′ may be liquid helium, mercury, sodium (500 to 1450° C.), sulphur, halides (e.g., SbBr3 or TiI4), indium, Cesium, NaK, potassium (400 to 1000° C.), lithium (900 to 1700° C.), sliver, ammonia, alcohol, methanol, ethanol, acetone, methyl alcohol, water (25 to 327° C.), naphthalene (330 to 450° C.), or other molten materials, depending on a desired operating temperature. For room temperature applications, water may be used as the working fluid. For higher temperature applications, mercury (523-923K), sodium (873-1473K) or indium (2000-3000K) may be used as the working fluid.

The material of the substrate 40′ is chosen to be compatible with the working fluid 50′. A wide selection of materials may be used to form the substrate 40′ for elevated temperature applications, including but not limited to, Stainless Steel, Incoloy, Titanium, Inconel, Tungsten, Niobium, Molybdenum, and Aluminum Nitride (AlN). When water is used as the working fluid 50′, the substrate 40′ may be made of copper. When ammonia is used as the working fluid 50′, the substrate 40′ may be made of aluminum.

In another form, the thermal phase diffuser 14′ may have only the plate portion 30′ without the shaft portion 32′. A separate shaft member may be used to be attached to the lower member 16 of the pedestal 10.

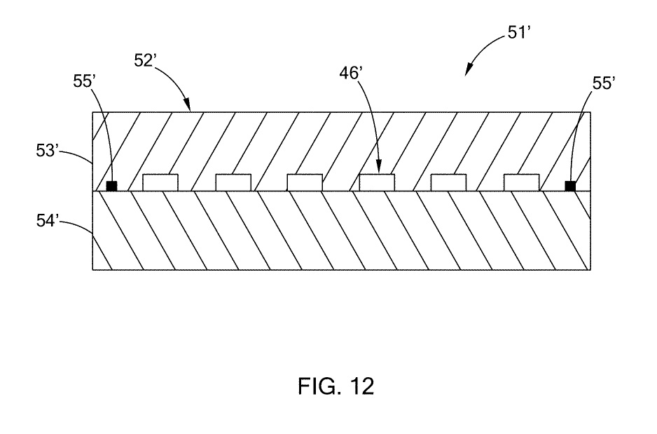

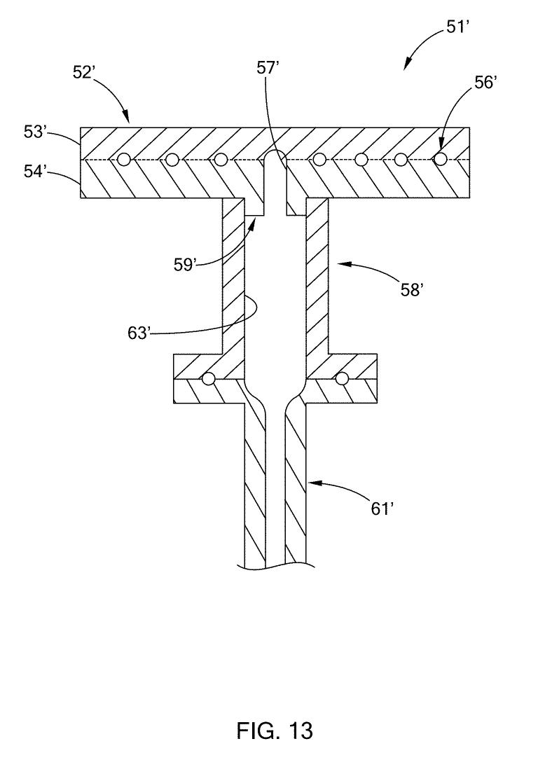

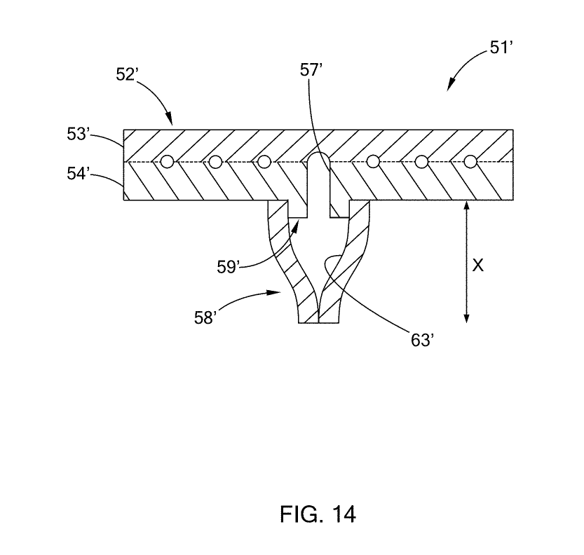

Referring to FIG. 12, a variant of a thermal phase diffuser 51′ having an OHP configuration is similar to that of FIG. 11, except that the substrate 52′ includes a first plate member 53′ and a second plate member 54′ that are bonded together at a bonding feature 55′ at their interface and along their periphery. The first and second plate members 53′ ad 54′ are made of a ceramic material, such as aluminum nitride (AlN), aluminum oxide (alumina), silicon carbide (SiC). At least one fluid channel 46′ is formed at the interface between the first and second plate members 53′ and 54′. The at least one fluid channel 46′ may be completely disposed in one of the first and second plate members 53′ and 54′ as shown in FIG. 12 or may be located in the middle of the substrate 52′ as shown in FIGS. 13 and 14. A working fluid 50′ flows inside the at least one fluid channel 46′ and oscillates in the plane of the substrate 52′ to form an OHP.

Referring to FIG. 13, to form an OHP in the ceramic substrate 52′, a first plate member 53′ and a second plate member 54′ made of a ceramic material are prepared, wherein at least one of the first plate member 53′ and the second plate member 54′ is formed with a trench. After the first and second plate members 53′ and 54′ are bonded and the trench is closed, the trench defines the fluid channel 46′. When both of the first and second plate members 53′ and 54′ are formed with a trench, the at least one least fluid channel 46′ is formed in the middle of the substrate 52′ as shown in FIGS. 13 and 14. The at least one fluid channel 46′ is a microchannel having dimensions necessary to allow operation of OHP. The cross section of the at least one fluid channel 46′ can have any shape including a rectangle (FIG. 12) or a circle (FIGS. 13 and 14), depending on the friction conditions desired for flow. A width or a diameter of the at least one fluid channel 46′ may be in the range of 100 μm to 1 mm, possibly up to 10 mm in some applications.

At least one of the first plate member 53′ and the second plate member 54′ may be formed with a bonding trench along a periphery of the first or second plate member and surrounding the at least one fluid channel 46′. An aluminum material is applied in the bonding trench to bond the first plate member 53′ to the second plate member 54′ and to form the bonding feature 55′ along the periphery of the first and second plate members 53′ and 54′. The aluminum material is applied in the bonding trench in a solid form, heated to a melting temperature of the aluminum material. The molten aluminum material completely fills in the bonding trench. When the molten aluminum material solidifies, a hermetic bonding is formed along the periphery of the first and second plate members 53′ and 54′ to form the bonding feature 55′.

The interface between the first and second plate members 53′ and 54′ and between adjacent sections of the fluid channel 46′ may also be bonded by the aluminum material. If the first and second plate members 53′ and 54′ are bonded only along their periphery, cross-flow of the working fluid along the interface may occur. However, oscillation of the working fluid may compensate for that.

Alternatively, the substrate 52′ may be formed by 3D printing to form the fluid channel 46′ in the substrate 52′. Therefore, the substrate 52′ has a monolithic structure and no bonding is necessary.

Referring to FIG. 13, alternatively, the ceramic substrate 52′ is shown to have a fluid channel 56′ having a circular cross section. Half of the fluid channel 56′ is disposed in the first plate member 53′ and another half of the fluid channel 56′ is disposed in the second plate member 54′ such that the fluid channel 56′ is formed in the middle of the ceramic substrate 52′. The second plate member 54′ further defines a cutout portion 57′ open to a bottom surface of the second plate member 54′. After the first and second plate members 53′ and 54′ are bonded by the bonding feature 55′ (shown in FIG. 12) and the at least one fluid channel 56′ is formed in the substrate 52′, a fill tube 58′ is aligned with the cutout portion 57′ of the second plate member 54′ and connected to the second plate member 54′ by a brazing material so that the channel 63′ of the fill tube 57′ is in fluid communication with the fluid channel 56′ of the ceramic substrate 52′. The second plate member 54′ may include a collar 59′ protruding from the bottom surface of the second plate member 54′ to facilitate bonding of the fill tube 58′ to the second plate member 54′ of the ceramic substrate 52′. The collar 59′ is disposed inside the fill tube 58′. The outer surface of the collar 59′ is brazed to an inner surface of the fill tube 58′.

The brazing material may be titanium-nickel, nickel-palladium, or other nickel based braze alloy. The fill tube 58′ allows the working fluid to be filled in the fluid channel 56′ during manufacturing. The fill tube 58′ may be made of nickel and may be directly brazed to the collar 59′. To improve brazing of the fill tube 58′ to the collar 59′ of the ceramic substrate 52′ and to avoid separation of the fill tube 58′ from the ceramic substrate 52′ during thermal cycling, a molybdenum layer (not shown) may be optionally deposited on the surface of the collar 59′ of the ceramic substrate 52′ before the brazing process. Molybdenum has a coefficient of thermal expansion between that of the fill tube 58′ and that of the ceramic substrate 52′. Therefore, the use of the molybdenum layer can reduce thermal stress at the interface between the ceramic substrate 52′ and the fill tube 58′ during thermal cycling. The thickness of the molybdenum layer may be in the range of 5 to 50.8 μm.

The fill tube 58′ may have a distal end brazed to a fill flange 61′ to help create a vacuum in the channel 56′ before the working fluid fills in the channel 56′ and to help filling of the working fluid in the channel 56′.

Referring to FIG. 14 after the working fluid fills in the fluid channel 56′ of the ceramic substrate 52′, the fill flange 59′ is removed and the distal end of the fill tube 58′ is crimped to seal the working fluid inside the fluid channel 56′. The length X of the crimped fill tube 58′ may depend on applications.

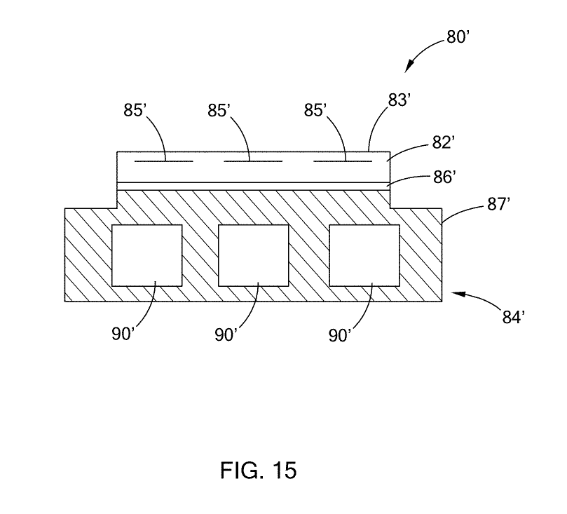

Referring to FIG. 15, a pedestal 80′ constructed in accordance with another form of the present disclosure is structurally similar to FIG. 7 except for the structure of the thermal phase diffuser. The pedestal 80′ includes an upper member in the form of an integrated electrostatic chuck (ESC) and an integrated thermal phase diffuser in the form of a cooling device. The shaft member of the pedestal 80′ is not shown in FIG. 15 and the description thereof is omitted herein for clarity. The pedestal 80′ of the present form may be operated at an operating temperature in the range of 150° C. to 300° C., which is significantly lower than the operating temperature of the pedestals 10, 60 of the first and second forms.

More specifically, the pedestal 80′ includes an ESC 82, a thermal phase diffuser in the form of a cooling device 84′, and a bonding layer 86′ for bonding the ESC 82′ to the cooling device 84′, and optionally a shaft member (not shown in FIG. 15) disposed under the cooling device 84′. The ESC 82′ includes a chuck body 83′ made of a ceramic material and electrodes 85′ embedded therein to providing the electrostatic chucking force to the wafer (not shown) disposed thereon. The cooling device 84′ may be a heat pipe having an OHP configuration and has a plate configuration. The cooling device 84′ includes a substrate 87′ and at least one channel 90′ defined in the substrate 87′ and extending in the plane of the substrate 87′. The working fluid flows inside the channel 90′. A peripheral portion of the substrate 87′ may function as an evaporator side and the center of the substrate 87′ may function as a condenser side. The operation of the cooling device 84′ is similar to the operation of the thermal plate portion 30′ of FIG. 11, differing in that a cooling source, instead of a heat source, is provided at the condenser side.

More specifically, the working fluid, which includes discrete fluid slugs and vapor bubbles, repeatedly flows in the channel 90′ between the evaporator side and the condenser side. When the working fluid flows to the cold condenser side proximate the cooling source, the working fluid is cooled by the cooling source and vapor bubbles of the working fluid condense proximate the cold condenser side. When the liquid slugs of the working fluid flows to the evaporator side, the liquid slugs of the working fluid absorb heat proximate the evaporator side to reduce the temperature of the substrate 87′ proximate the evaporator side. The liquid slugs are partially evaporated so that the vapor bubbles absorb the fluid's latent heat and expands. By repeatedly moving between the hot evaporator side and the cold condenser side, the working fluid causes the thermal power Q to flow between the center and the peripheral portion of the substrate 87′. Alternatively, the cooling source may be provided at the peripheral portion to make the peripheral portion a condenser side of the heat pipe and to make the center an evaporator side of the heat pipe. The substrate 87′ of the cooling device 84 may be made of copper and the working fluid may be water.

In this form, the cooling device 84′ is shown to be applied to a bottom surface of the ESC 82′. Alternatively, the cooling device 84′ may be embedded within the chuck body 83′ of the ESC 82′.

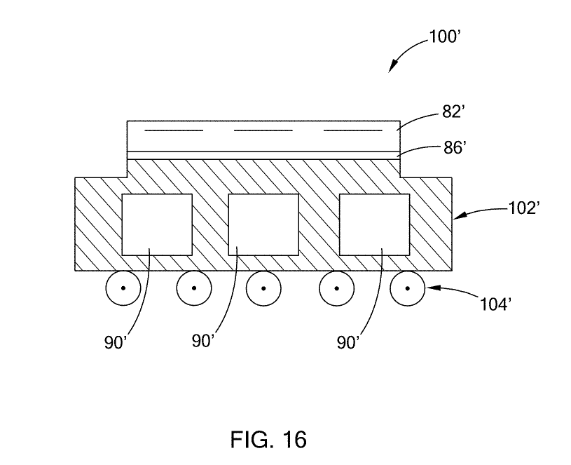

Referring to FIG. 16, a pedestal 100′ constructed in accordance with the teachings of yet another form is structurally similar to FIG. 8, except for the thermal phase diffuser. The pedestal 100′ includes an upper member in the form of an integrated ESC and a thermal phase diffuser in the form of a heating/cooling device. The shaft member of the pedestal 100′ is optional and is not shown in FIG. 16 and thus the description thereof is omitted herein for clarity.

More specifically, the pedestal 100′ includes an ESC 82′ similar to that of FIG. 15, a thermal phase diffuser in the form of a heating/cooling device 102′, and a supplemental heater 104′ disposed at a bottom surface of the heating/cooling device 102′, which may be a resistive heater in one form of the present disclosure. The supplemental heater 104′ is disposed outside the ceramic stack to minimize thickness and thermal resistance. The heating/cooling device 102′ has a structure similar to that of the cooling device 84′ of FIG. 15 except that the heating/cooling device 102′ can be used for both heating and cooling the ESC 82′. Whether a heat pipe having an OHP configuration is used for heating or cooling depends on whether a heat source or a cooling source is provided for the heat pipe. When a heat source is provided to heat the heating/cooling device 102′, the OHP is used a heater. When a cooling source is provided to cool the heating/cooling device 102′, the OHP is used as a cooling device.

The supplemental heater 104′ may be a less expensive and lower precision heater attached to the bottom surface of the heating/cooling device 102′. In the present form, the substrate of the heating/cooling device 102′ may be made of copper and the working fluid may be water.

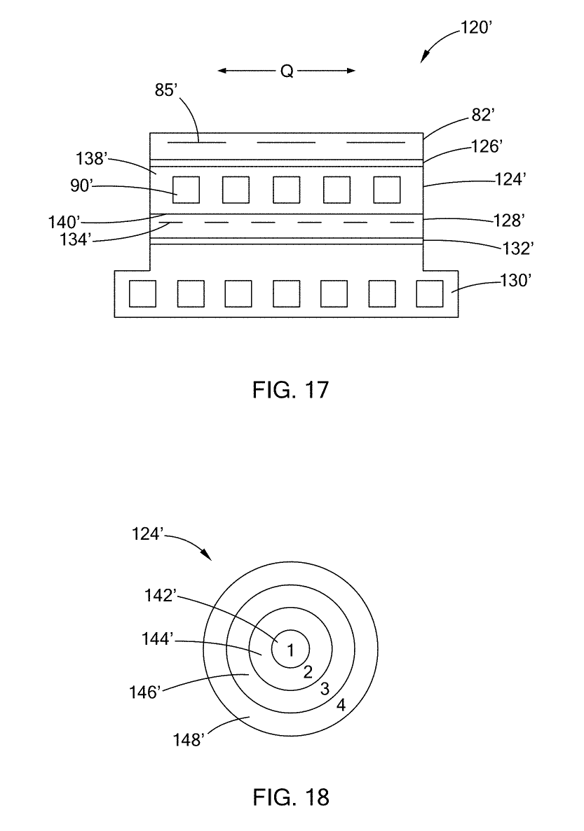

Referring to FIG. 17, the pedestal 120′ constructed in accordance with another form of the present disclosure is structurally similar to FIG. 9 and includes an integrated diffuser. The tubular shaft member is optional and is not shown in FIG. 17.

More specifically, the pedestal 120′ includes an upper member in the form of an ESC 82′, a thermal phase diffuser in the form of a diffuser 124′, a first bonding layer 126′ between the ESC 82′ and the diffuser 124′, a heater 128′, a base plate 130′, and a second bonding layer 132′ disposed between the heater 128′ and base plate 130′. The ESC 82′ is similar to the ones of FIGS. 15 and 16. The heater 128′ may be a conventional heater including a plurality of resistive heating elements 134′. The diffuser 124′ is a heat pipe with an OHP configuration, wherein at least one channel having a serpentine shape extends in the plane of the diffuser 124′. As in FIGS. 15 and 16, the hot evaporator side and the cold condenser side of the heat pipe are disposed along the radial direction of the diffuser 124′. The working fluid “oscillates” within the channel 138′ in the radial direction. Therefore, the thermal power Q moves in a radial direction, either inwardly or outwardly.

Referring to FIG. 18, the diffuser 124′ has a plate configuration and defines a plurality of annular regions, for example, region 1, region 2, region 3, region 4. The annular regions are in different radial positions relative to the center of the diffuser 124′. The diffuser 124′ allows for radial tuning. A heating surface may not provide uniform heating along the radial direction of the heating surface due to the presence of heat sinks along the peripheral portion of the diffuser 124′. The diffuser 124′ allows for heat transfer along a radial direction, either from a center toward a peripheral end, or from a peripheral end toward the center. The center of the diffuser 124′ may have a temperature higher or lower than the temperature of the peripheral end of the diffuser 124′, thereby fine-tuning the temperature of the heating surface along the radial direction to achieve a more uniform heating surface.

Alternatively, the diffuser 124′ may include a plurality of concentric ring plates 142′, 144′, 146′, 148′, each ring plate including a heat pipe structure to conduct heat transfer within each ring plate and in the radial direction. Therefore, one radial end of the ring plate has a temperature higher than the other radial end of the ring plate.

The pedestals with a thermal phase diffuser configured to include a vapor-chamber-type heat pipe or an OHP configuration has the advantages of longer life, rapid heating/cooling, low profile and reduced manufacturing costs. The heat pipe, either vapor-chamber-type heat pipe or OHP, can have longer life with no maintenance due to the unique structure of the heat pipe. Moreover, the thermal conductivity of the heat pipe can exceed 5000 W/mK. Therefore, the thermal phase diffuser having a vapor-chamber-type heat pipe or an OHP structure can more rapidly heat/cool a heating/cooling target. A thermal phase diffuser with the OHP configuration does not need any wick structure and thus the heat pipe and the thermal phase diffuser including the heat pipe can have a low profile and reduced thickness. The pedestals constructed in accordance with the teachings of the present disclosure have fewer components and thus have a simpler structure. When the substrate is made of ceramic material, selection of the working fluid is increased due to the low reactivity of the ceramic material with the working fluid. In addition, ceramic materials have excellent thermal conductivity to enhance heat transfer to other system elements.

The pedestals constructed in accordance with the teachings of the present application has the advantages of obtaining high temperature capability exceeding 1000° C. The only limit on operating temperature is the bonding between the upper member 12 and the lower member 16. Moreover, the pedestal of the present disclosure has significantly high thermal conductivity/heat transfer within plane of heat pipe plate, compared to a typical pedestal, and can obtain high uniformity (approximately ±0.1° C.) above approximately 400° C. The pedestal has a simplified design/manufacturing with relatively low profile as compared to other aluminum nitride pedestal which requires separate heating and cooling elements.

Gas Line Heating Assemblies

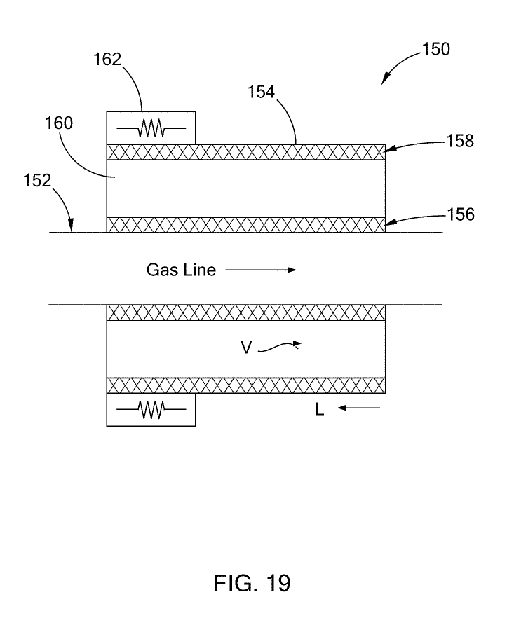

Referring to FIG. 19, a thermal phase diffuser may be configured to have a tubular configuration to form a gas line heating assembly 150 for heating a gas line 152 therethrough. The gas line heating assembly 150 of the present form has a vapor-chamber-type heat pipe. The thermal phase diffuser includes an outer shell 154, a first wick structure 156 and a second wick structure 158 surrounded by the tubular shell 154. The first wick structure 156 defines a central channel through which the gas line 152 is inserted. The second wick structure 158 surrounds the first wick structure 156 and defines an annular vapor guiding channel 160 between the first wick structure 156 and the second wick structure 158. A working fluid is contained inside the tubular shell 154. The vapor of the working fluid flows in the annular vapor guiding channel 160 in a direction parallel to the axis of the gas line 152. The gas line heating assembly 150 may further include an additional heater 162 around the tubular shell 154 to provide intermittent heating. The gas line heating assembly 150 of the present form can maintain a high level thermal uniformity along the length of the gas line 152.

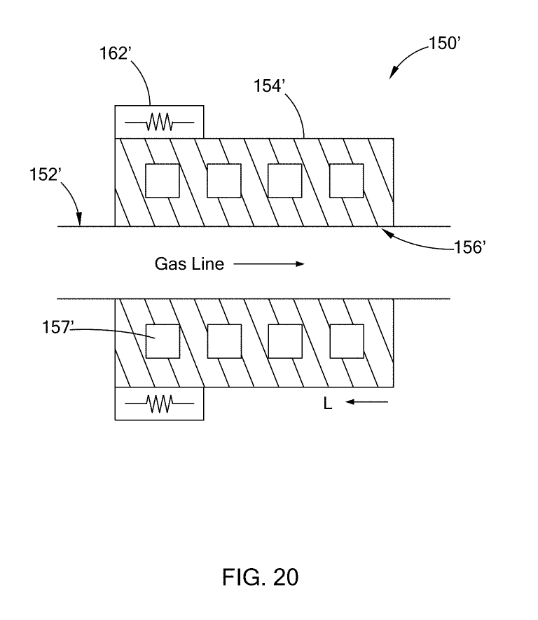

Referring to FIG. 20, a variant of a thermal phase diffuser is configured to have a tubular configuration to form a gas line heating assembly 150′ for heating a gas line 152′ therethrough. The gas line heating assembly 150′ in the current form has an OHP configuration. The gas line heating assembly 150′ includes a tubular substrate 154′ defining a central channel 156′ in which a gas line 152′ is inserted and at least one channel 157′ having a serpentine shape. A working fluid “oscillates” inside the channel 157′ between the opposing longitudinal ends in a direction parallel to the axis of the gas line 152′. The gas line heating assembly 150′ may further include an additional heater 162′ around a portion of the tubular substrate 154′ to provide intermittent heating. The gas line heating assembly 150′ of the present form can maintain a high level thermal uniformity along the length of the gas line 152′ by directing the heat from the additional heater 162′ toward the portion of the gas line distal from the additional heater 162′.

Thermal System with Heat Pipe Configuration

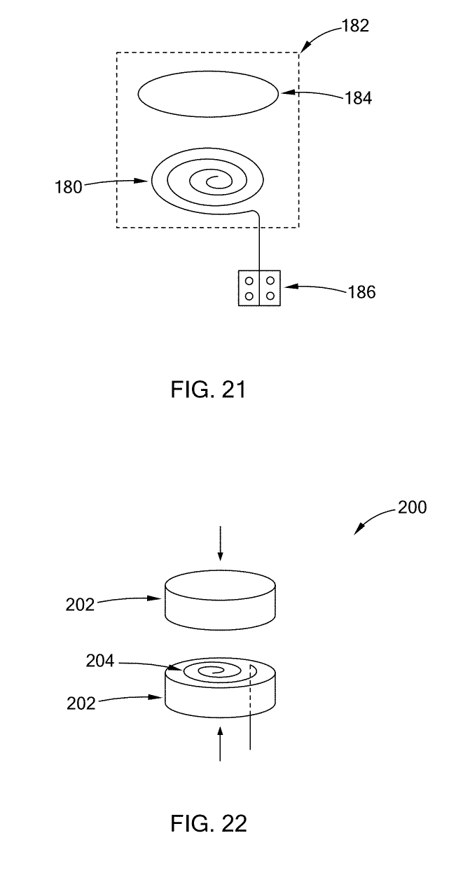

Referring to FIG. 21, a thermal system 180 constructed in accordance with the teachings of the present disclosure is configured to provide radiative heat to a wafer 184 in a semiconductor processing chamber 182. Typically, the radiative heat is provided by a tubular heater. In the present form, the thermal system 180 may include a vapor-chamber type heat pipe similar to the heating cooling/device 102 of FIG. 8 or an OHP similar to the heating/cooling device 102′ of FIG. 16, but is configured to have a spiral shape in plan view and is routed out of the semiconductor processing chamber 182 to an external heat source 186. The thermal system 180 may radiate heat to the wafer holder just like the tubular heater, but with a higher degree of thermal uniformity.

Referring to FIG. 22, a variant of a thermal system 200 constructed in accordance with the teachings of the present disclosure is a heating plate which includes a substrate 202 and a heater element 204 embedded in the substrate 202. The heater element 204 may include a vapor-chamber type heat pipe structurally similar to the heating/cooling device 102 of FIG. 8 or an OHP structurally similar to the heating/cooling device 102′ of FIG. 16. The heating plate may be used with a metal pedestal (e.g. stainless or Inconel). The heater element 204 may be embedded within the pedestal or be pressed in place.

Temperature Sensor with Heat Pipe Configuration

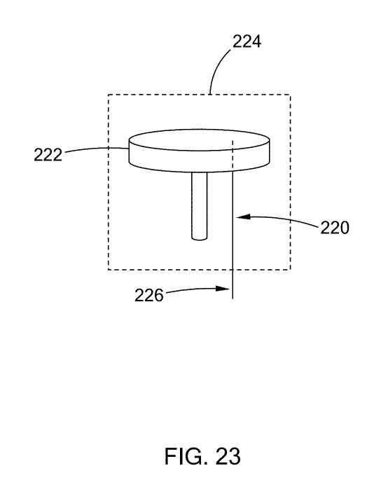

Referring to FIG. 23, a thermal system 220 constructed in accordance with the teachings of the present disclosure is used as a temperature sensor 220 for measuring a temperature of a wafer holder 222 disposed inside a semiconductor processing chamber 224. The temperature sensor 220 may include a vapor-chamber-type heat pipe construction, or an OHP, and has a very small diameter. Heat is transferred from the wafer holder 222 through the temperature sensor in the form of a heat pipe to an object (not shown) outside the chamber 224. The object becomes a measuring point 226. By measuring the temperature of the object, the heat transferred from the wafer holder 222 to the object may be determined. Therefore, the temperature of the wafer holder 222 can be measured externally, i.e., outside the processing chamber 224, rather than in situ. The heat pipe may be used for precise temperature measurement outside the wafer holder assembly, or outside the chamber 224 altogether.

It should be noted that the disclosure is not limited to the form described and illustrated as examples. A large variety of modifications have been described and more are part of the knowledge of the person skilled in the art. For example, although the teachings of the present disclosure are shown and described relative to a pedestal for semiconductor processing applications, it should be understood that a variety of other applications may be used while remaining within the scope of the present disclosure. These and further modifications as well as any replacement by technical equivalents may be added to the description and figures, without leaving the scope of the protection of the disclosure and of the present patent.

What is claimed is:

1. An assembly comprising:
an upper member;
a lower member; and
a thermal phase diffuser disposed between the upper member and the lower member within a hermetically sealed volume,
wherein the thermal phase diffuser diffuses heat by way of a phase change of a working fluid within the hermetically sealed volume.

2. The assembly according to claim 1, further comprising a filling material disposed within a gap between the thermal phase diffuser and the lower member.

3. The assembly according to claim 2, wherein the filling material includes a high temperature compressible material.

4. The assembly according to claim 2, wherein the filling material is selected from a group consisting of Grafoil, aluminum nitride (AlN) powder, ceramic paste, and flexible graphite/graphene.

5. The assembly according to claim 1, further comprising a bonding layer disposed between the upper member and the thermal phase diffuser.

6. The assembly according to claim 5, wherein the bonding layer includes a titanium-nickel braze alloy.

7. The assembly according to claim 1, wherein the upper member includes an upper wall and a peripheral wall extending downwardly from the upper wall, the thermal phase diffuser being surrounded by the peripheral wall of the upper member.

8. The assembly according to claim 7, wherein the lower member is bonded to the peripheral wall of the upper member.

9. The assembly according to claim 1, wherein the upper member and the lower member are made of different materials.

10. The assembly according to claim 1, wherein the thermal phase diffuser includes a tubular shell having a T-shape cross section.

11. The assembly according to claim 1, wherein the thermal phase diffuser further includes a wick structure, the wick structure defining a vapor guiding channel.

12. The assembly according to claim 11, wherein vapor of the working fluid flows in the vapor guiding channel and liquid of the working fluid flows along the wick structure and outside the vapor guiding channel.

13. The assembly according to claim 12, wherein the vapor of the working fluid flows in a direction perpendicular to the upper member.

14. The assembly according to claim 1, wherein the thermal phase diffuser includes a plate portion and a shaft portion extending from a lower surface of the plate portion and being perpendicular to the plate portion.

15. The assembly according to claim 14, further comprising a shaft member disposed under the lower member, the filling material also disposed between the shaft member and the shaft portion of the thermal phase diffuser.

16. The assembly according to claim 1, wherein the working fluid is selected from a group consisting of liquid helium, mercury, sodium, sulphur, halides, indium, Cesium, NaK, potassium, lithium, sliver, ammonia, alcohol, methanol, ethanol, acetone, methyl alcohol, water, Naphthalene, or other molten materials.

17. The assembly according to claim 1, further comprising a resistive heater surrounding a portion of the thermal phase diffuser.

18. The assembly according to claim 1, wherein the upper member is bonded to the lower member.

19. The assembly according to claim 1, wherein the upper member and the lower member are a single unitized part.

20. An assembly comprising:
a ceramic substrate defining a hermetically sealed fluid channel containing a working fluid; and
a thermal phase diffuser disposed within the hermetically sealed fluid channel,
the working fluid flowing in the hermetically sealed fluid channel and including a plurality of discrete liquid slugs and vapor bubbles.

21. The assembly according to claim 20, wherein the ceramic substrate is Aluminum Nitride (AlN).
